(19) United States
(12) Patent Application Publication
(10) Pub. No.: US 2026/0096384 A1
(43) Pub. Date: Apr. 2, 2026

(54) WAFER HOLDER FOR PROVIDING EVEN TEMPERATURE DISTRIBUTION

(71) Applicant: Skytech Inc., Hsinchu County (TW)

(72) Inventors: CHUN-FU WANG, Hsinchu County (TW); CHI-HUNG CHENG, Hsinchu County (TW); YAO-SYUAN CHENG, Hsinchu County (TW); CHI-HSIANG LIU, Hsinchu County (TW); KUO-JU LIU, Hsinchu County (TW); CHING-LIANG YI, Hsinchu County (TW)

(21) Appl. No.: 18/980,831

(22) Filed: Dec. 13, 2024

(30) Foreign Application Priority Data
Sep. 29, 2024 (TW) 113137182

(51) Int. Cl. H01L 21/67; H01L 21/683

(52) U.S. Cl. CPC H10P 72/0434; H10P 72/70

(57) ABSTRACT

This invention relates to a wafer holder for providing even temperature distribution, which comprises a support assembly and a diffusion unit. The diffusion unit is made of a porous material and is disposed on a top surface of the support assembly. The diffusion unit includes a main body, a plurality of protrusions, and at least one diffusion channel, wherein the protrusions and the diffusion channel are disposed on a bearing surface of the main body. A gas is transmitted to the diffusion unit from an inlet pipeline of the support assembly, and then transmitted through pores of the diffusion unit to the bearing surface, and comes into contact with the wafer on the diffusion unit to adjust the temperature of the wafer, and is beneficial for improving the uniformity of the temperature distribution of the wafer.

### CROSS-REFERENCE TO RELATED APPLICATIONS

This non-provisional application claims priority claim under 35 U.S.C. § 119(a) on Taiwan Patent Application No. 113137182 filed Sep. 29, 2024, the entire contents of which are incorporated herein by reference.

### TECHNICAL FIELD

This invention is a wafer holder, and more particular to a wafer holder for providing even temperature distribution.

### BACKGROUND

Chemical vapor deposition (CVD), physical vapor deposition (PVD), and atomic layer deposition (ALD) are thin film deposition processes that are commonly used in the manufacturing of integrated circuits, light-emitting diodes, and displays.

A deposition equipment is primarily composed of a chamber and a wafer holder, wherein the wafer holder is located in the chamber and is used to hold at least one wafer. Take PVD as an example, a target material is required to be placed in the chamber facing the wafer on the wafer holder. During PVD process, an inert gas and/or a reactant gas is transported into the chamber, bias voltage is supplied respectively to the target material and the wafer holder, and the wafer is heated by the wafer holder. The inert gas in the chamber turns into ionized inert gas due to the effect of high voltage electric field, wherein the ionized inert gas is attracted by the bias voltage on the target material and bombards the target material. The target material atoms or particles splashed from the target material are attracted by the bias voltage on the wafer holder and deposit on the surface of the heated wafer to form a thin film on the surface of the wafer.

In specific, the stability and uniformity of temperature generated by the wafer holder impacts greatly on the quality of thin films deposited on the surface of the wafer, and thus how to make the wafer holder generate stable and uniform temperature is an important issue in thin film deposition process.

### SUMMARY

In conventional deposition processes, the temperature of a wafer holder is often adjusted to ensure uniform film thickness deposited on the wafer surface. This invention introduces a wafer holder for providing even temperature distribution to the wafer on the wafer holder. This is achieved through a diffusion unit made of porous material, which evenly distributes heating gas or cooling gas to the wafer that is placed on the diffusion unit, resulting in a more consistent temperature profile and improved process quality.

One object of the invention is to provide a wafer holder for providing even temperature distribution, wherein the diffusion unit is able to provide a gas with a uniform distribution to the bottom surface of the wafer, thereby avoiding excessive gas concentration in a part of the bottom surface of the wafer, and thus making the temperature distribution of each part of the wafer more uniform.

One object of this invention is to provide a wafer holder for providing even temperature distribution, wherein the diffusion unit is able to provide a uniform and gentle gas flow to the wafer, thereby avoiding the situation where the gas provided by the diffusion unit blows the wafer and causes the wafer to displace relative to the wafer holder.

Furthermore, the gas pressure provided by the diffusion unit can be adjusted according to the weight of the wafer, thus the wafer can be stably placed on the surface of the wafer holder without the use of the electrostatic chuck or the clamp ring.

To achieve the foregoing objectives, this disclosure provides a wafer holder for providing even temperature distribution, comprising a support assembly and a diffusion unit. The support assembly comprises at least one recess disposed on a top surface of the support assembly, and an inlet pipeline connected to the recess for supplying a gas to the recess located on the top surface of the support assembly. The diffusion unit is located on the top surface of the support assembly, and the diffusion unit is a porous material. The diffusion unit comprises: a main body; a plurality of protrusions located on a bearing surface of the main body for supporting at least one wafer; and at least one diffusion channel located between the plurality of protrusions.

This disclosure provides another wafer holder for providing even temperature distribution, comprising a support assembly and a diffusion unit. The support assembly comprises at least one recess formed on a top surface of the support assembly, and an inlet pipeline connected to the recess for supplying a gas to the recess located on the top surface of the support assembly. Thu diffusion unit is used to support at least one wafer, and located on the top surface of the support assembly. The diffusion unit is a porous material, and comprises a first diffusion region, and a second diffusion region located outer side of the first diffusion region, wherein a gas permeability of the first diffusion region is different from that of the second diffusion region.

### BRIEF DESCRIPTION OF THE DRAWINGS

FIG. 1 is a sectional view of a wafer holder for providing even temperature distribution according to an embodiment the invention.

FIG. 2 is a three-dimensional exploded view of the wafer holder for providing even temperature distribution according to an embodiment the invention.

FIG. 3 is a three-dimensional exploded view of the wafer holder for providing even temperature distribution according to another embodiment the invention.

### DETAILED DESCRIPTION

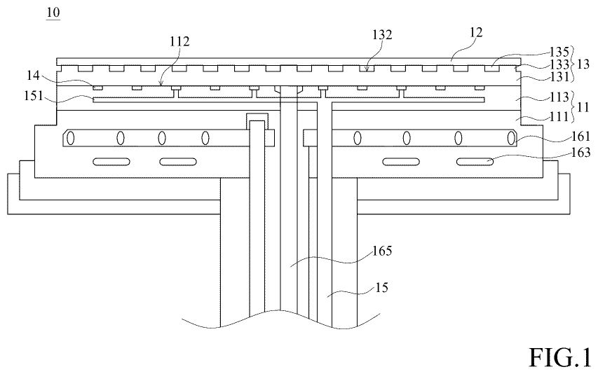

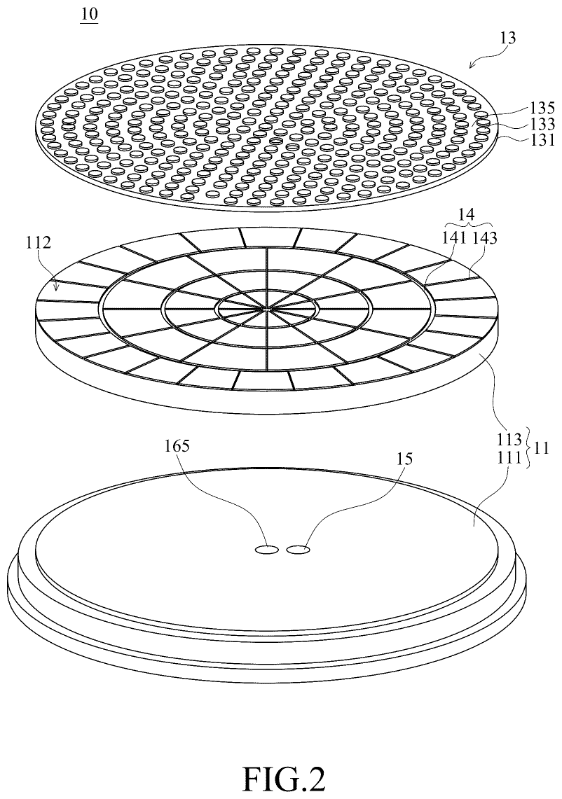

FIG. 1 and FIG. 2 are respectively a sectional view and a three-dimensional exploded view of a wafer holder for providing even temperature distribution according to an embodiment the invention. As shown, the wafer holder 10 is used to support at least one wafer 12, and mainly includes a support assembly 11 and a diffusion unit 13. The support assembly 11 is used to connect the diffusion unit 13, and the diffusion unit 13 is used to support the at least one wafer 12.

In one embodiment of this invention, the support assembly 11 includes a base 111 and a carrier unit 113, wherein the carrier unit 113 is disposed on the base 111. For example, the carrier unit 113 may be a titanium disk, and the carrier unit 113 can be fixed to the base 111 by a plurality of screws.

At least one recess 14 can be provided on a top surface 112 of the support assembly 11, as shown in FIG. 2. The recess 14 may include at least one annular recess 141 and at least one radial recess 143. The annular recess 141 and the radial recess 143 can be provided on a top surface 112 of the carrier unit 113 of the support assembly 11, wherein the annular recess 141 and the radial recess 143 are connected to each other. For example, the carrier unit 113 of the support assembly 11 may be disk-shaped, and the annular recess 141 and the radial recess 143 are provided on the top surface 112 of the disk-shaped carrier unit 113.

At least one inlet pipeline 15 can be provided in the support assembly 11, and the inlet pipeline 15 is connected to the recess 14 located on the top surface 112 of the support assembly 11. For example, the inlet pipeline 15 can be disposed inside the base 111 and/or the carrier unit 113, and connected to the recess 14 on the top surface 112 of the carrier unit 113.

In practical applications, gas can be transported to the recess 14 of the support assembly 11 via the inlet pipeline 15, allowing the gas to flow within the recess 14, wherein the gas can be an inert gas or a non-reactive gas. For example, cooling gas or heating gas can be transported to the annular recess 141 and the radial recess 143 of the recess 14 via the inlet pipeline 15. In one embodiment of the invention, at least one branch pipeline 151 may be provided inside the carrier unit 113, and the branch pipeline 151 is connected to the recess 14 on the carrier unit 113. Further, when the carrier unit 113 is connected to the base 111, the branch pipeline 151 of the carrier unit 113 is connected to the inlet pipeline 15 of the base 111, so that the inlet pipeline 15 can transport gas to the recess 14 via the branch pipeline 151.

In conventional deposition processes, the wafer 12 is directly placed on the top surface 112 of the support assembly 11, such as placing the wafer 12 on the top surface 112 of the carrier unit 113. As gas is supplied from the inlet pipeline 15 or the branch pipeline 151 to the recess 14, most of the gas will directly blows toward the bottom surface of the wafer 12. Subsequently, the gas flows along the recess 14 between the wafer 12 and the top surface 112 of the support assembly 11. The gas flowing in the recess 14 comes into contact with the bottom surface of the wafer 12 to adjust the temperature of the wafer 12 through heat conduction and convection.

During the deposition process, an inert gas or a reactant gas may be directed towards the upper surface of the wafer. Further, the gas blown toward the bottom surface of the wafer 12 from the inlet pipeline 15 or the branch pipeline 151 will create an upward force on a local area of the wafer 12. When the upward force exerted by the gas on the bottom surface of the wafer 12 is greater than the weight of the wafer 12 and the force exerted by the gas on the upper surface of the wafer 12, the wafer 12 will be lifted away from the support assembly 11, causing the wafer 12 to displace relative to the support assembly 11.

To avoid the aforementioned issue, an electrostatic chuck (e-chuck) is typically installed inside the support assembly 11, and the wafer 12 is adsorbed onto the support assembly 11 via electrostatic force. Alternatively, a clamp ring can be used to apply pressure to the upper surface of the wafer 12 to secure the wafer 12 on the support assembly 11.

In practical applications, in addition to the inlet pipeline 15 and branch pipeline 151, the support assembly 11 typically includes a heating unit 161, a cooling unit 163, and/or a bias electrode 165. Therefore, the additional installation of the electrostatic chuck within the support assembly 11 undoubtedly increases the complexity, manufacturing difficulty, and setup cost of the wafer holder 10. Additionally, although the setup cost of the clamp ring is lower than that of the electrostatic chuck, the clamp ring directly applies pressure to the upper surface of the wafer 12 during use, which may cause damage to the wafer 12.

Further, to increase the contact area between the gas in the recess 14 and the bottom surface of the wafer 12, the density of the recesses 14 provided on the top surface 112 of the support assembly 11 may be increased to improve the temperature uniformity of the wafer 12. However, in practical applications, the density of the recesses 14 provided on the top surface 112 of the support assembly 11 cannot be increased indefinitely. Therefore, the effect of improving the temperature uniformity of the wafer 12 through the provision of recesses 14 is still limited.

Accordingly, this invention proposes providing a diffusion unit 13 on the top surface 112 of the support assembly 11, and placing the wafer 12 on the diffusion unit 13. The diffusion unit 13 can be made of a porous material, such as ceramic, silicon carbide (SiC), or foamed metal, and can be fixed to the top surface 112 of the support assembly 11 and/or the carrier unit 113 using screws.

The gas supplied from the inlet pipeline 15 and/or branch pipeline 151 to the recess 14 located on the top surface 112 of the support assembly 11 will be transmitted to the bottom surface of the wafer 12 via the diffusion unit 13. The diffusion unit 13 is made of the porous material, through which the gas from the inlet pipeline 15, branch pipeline 151, and/or recess 14 is transmitted through the pores within the diffusion unit 13 to the bearing surface 132 of the diffusion unit 13, and then discharged from between the diffusion unit 13 and the wafer 12.

The diffusion unit 13 of this invention is made of the porous material and has a permeability of 30% to 70%, enabling the diffusion unit 13 to provide a uniformly distributed and gently pressurized gas to the bottom surface of the wafer 12. In contrast, if the gas is directly supplied to the wafer 12 through the inlet pipeline 15 and/or branch pipeline 151 of the support assembly 11, the gas will typically impinge on a specific area of the wafer 12. This may result in a higher pressure on the specific area of the bottom surface of the wafer 12, causing the wafer 12 to displace relative to the wafer holder 10, thus requiring the additional installation of the electrostatic chuck or the clamp ring to fix the wafer 12 on the wafer holder 10. In addition, the gas concentrated in the specific area of the bottom surface of the wafer 12 is not conducive to forming the uniform temperature distribution on the wafer 12, and will affect the quality of subsequent deposition processes.

By directing the uniform and gentle gas flow towards the bottom surface of the wafer 12 through the diffusion unit 13, this invention is able to reduce the concentration of gas in specific areas of the wafer 12. This not only contributes to improved temperature uniformity of the wafer 12 but also prevents the gas from displacing the wafer 12 on the diffusion unit 13. Specifically, the force exerted by the gas provided by the diffusion unit 13 on the bottom surface of the wafer 12 can be calculated based on the weight of the wafer 12 and the force of the gas acting on the upper surface of the wafer 12. For example, the force exerted by the gas output from the diffusion unit 13 on the bottom surface of the wafer 12 is less than the weight of the wafer 12, or less than the sum of the weight of the wafer 12 and the force of the gas acting on the upper surface of the wafer 12.

In this way, even without the use of the electrostatic chuck or the clamp ring, the wafer 12 can still be stably placed on the diffusion unit 13 of the wafer holder 10 during the deposition process, preventing the wafer 12 from displacing relative to the wafer holder 10 and the diffusion unit 13. By eliminating the need for the electrostatic chuck or the clamp ring, the manufacturing difficulty and cost of the wafer holder 10 can be significantly reduced.

In one embodiment of the invention, the diffusion unit 13 may include a main body 131, a plurality of protrusions 133, and at least one diffusion channel 135, wherein the shape of the main body 131 may be similar to that of the support assembly 11 and/or the carrier unit 113. For example, the main body 131 and the carrier unit 113 may be disk-shaped. The plurality of protrusions 133 are provided on the bearing surface 132 of the main body 131 and are used to support the wafer 12. The protrusions 133 may be columnar protrusions of any geometric shape. For example, the protrusions 133 may be cylindrical protrusions. At least one diffusion channel 135 is formed on the bearing surface 132 by the plurality of protrusions 133, wherein the diffusion channel 135 is located between adjacent protrusions 133. For example, the protrusions 133 and the diffusion channel 135 are provided on the bearing surface 132 of the main body 131 of the diffusion unit 13.

The diffusion unit 13 is made of the porous material and has multiple pores. For example, the main body 131 and the protrusions 133 are made of the porous material and has multiple pores, and the gas can be transmit to the bottom surface of the wafer 12 via the multiple pores of the main body 131, the protrusions 133 and/or the diffusion channel 135. Specifically, the gas transmitted into the diffusion unit 13 through the inlet pipeline 15, branch pipelines 151, and/or recess 14 of the support component 11 may initially accumulate within the diffusion unit 13. When the gas pressure within the diffusion unit 13 accumulates to a certain level, the gas will be discharged through the pores on the surface of the diffusion unit 13. At this time, the gas jetted out from the pores on the bearing surface 132 of the diffusion unit 13 has a relatively high pressure, and may cause relative displacement between the wafer 12 and the diffusion unit 13.

To address this, this invention further provides protrusions 133 on the bearing surface 132 of the diffusion unit 13. When the gas accumulated in the diffusion unit 13 is discharged through the pores of the bearing surface 132 and/or the diffusion channel 135, it can be discharged through the diffusion channels 135 between the plurality of protrusions 133, thereby avoiding the entire gas pressure accumulated in the diffusion unit 13 from acting on the bottom surface of the wafer 12 and helping to reduce the gas pressure accumulated between the diffusion unit 13 and the wafer 12. In addition, the protrusions 133 can further provide frictional force between the diffusion unit 13 and the wafer 12, which can effectively prevent the discharged gas from causing the wafer 12 to displace relative to the diffusion unit 13.

In practical applications, the thickness of the diffusion unit 13 at the location where the protrusions 133 are provided is greater than the thickness at the location where the diffusion channels 135 are provided. Theoretically, the gas accumulated in the diffusion unit 13 may be discharged first through the pores on the diffusion channels 135, and then through the pores on the protrusions 133. Initially, the gas pressure discharged from the pores on the diffusion channels 135 may be generally greater than the gas pressure discharged from the pores on the protrusions 133. Further, due to the small gap between the diffusion channels 135 and the wafer 12, it can avoid the gas with higher pressure discharged from the diffusion channels 135 from directly acting on the bottom surface of the wafer 12, and is beneficial to reduce the chance of the wafer 12 being displaced due to the pressure output from the diffusion unit 13.

In one embodiment of the invention, the total area of the protrusions 133 may be about 30% to 70% of the bearing surface 132 of the main body 131 of the diffusion unit 13, the height of the protrusions 133 may be about 0.3 mm to 1 mm, the diameter of the protrusions 133 may be about 6 mm to 10 mm, and the gap between adjacent protrusions 133 may be about 1 mm to 5 mm. The above proportions of the total area of the protrusions 133 to the bearing surface 132, the height, diameter, and gap of the protrusions 133 are merely embodiments of the invention and do not limit the scope of the invention.

Furthermore, when the gas within the diffusion unit 13 is discharged from the bearing surface 132 or the diffusion channel 135, the wafer 12 will still be in contact with the protrusions 133 of the diffusion unit 13, resulting in frictional force between the diffusion unit 13 and the bottom surface of the wafer 12, and can further prevent the wafer 12 from displacing relative to the diffusion unit 13.

Furthermore, a material with higher thermal conductivity can be selected to manufacture the diffusion unit 13, and the thermal conductivity of the diffusion unit 13 may be greater than that of the carrier unit 113. For example, the carrier unit 113 of the support assembly 11 is usually a titanium disk with a thermal conductivity of about 21.9 W/mK, while the diffusion unit 13 made of silicon carbide (SiC) has a thermal conductivity of about 120˜270 W/mK. In this case, the thermal conductivity of the diffusion unit 13 is much higher than that of the carrier unit 113, and the efficiency of heating or cooling the wafer 12 can be improved.

In summary, by installing the diffusion unit 13 on the support assembly 11 and/or the carrier unit 113, a stable and uniform gas flow can be provided to the wafer 12 through the diffusion unit 13, such as through the multiple pores on the main body 131, the protrusions 133 and/or the diffusion channel 135, thereby improving the overall temperature uniformity of the wafer 12. Furthermore, by setting protrusions 133 and diffusion channels 135 on the bearing surface 132 of the diffusion unit 13 and adjusting the gas pressure provided by the diffusion unit 13 to the wafer 12, the wafer 12 can be stably placed on the diffusion unit 13 without using the electrostatic chuck or the clamp ring. This is beneficial for simplifying the structure and design difficulty of the wafer holder 10 and reducing the manufacturing cost of the wafer holder 10.

In one embodiment of the invention, the wafer holder 10 may be provided with at least one heating unit 161, at least one cooling unit 163, and/or at least one bias electrode 165. The heating unit 161 and the cooling unit 163 are respectively used for heating and cooling the wafer 12 on the wafer holder 10 to adjust the temperature of the wafer 12, and the bias electrode 165 is used to form a radio frequency (RF) bias. For example, the heating unit 161 may be a resistive heater, and the cooling unit 163 may be a pipeline with a cooling fluid therein, wherein the heating unit 161 and the cooling unit 163 may be disposed in the base 111 and heat or cool the wafer 12 through the base 111, the carrier unit 113, and/or the diffusion unit 13.

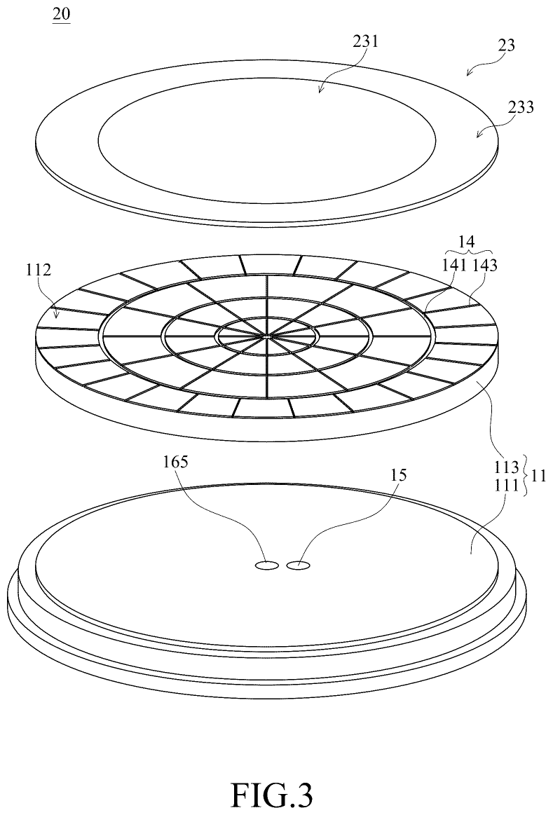

Referring to FIG. 3 is a three-dimensional exploded view of the wafer holder for providing even temperature distribution according to another embodiment the invention. With reference to FIG. 1 and FIG. 2, the wafer holder 20 is used to support at least one wafer 12, and mainly includes a support assembly 11 and a diffusion unit 23. The support assembly 11 is connected with the diffusion unit 23, and at least one wafer 12 is supported through the diffusion unit 23.

At least one recess 14 can be provided on the top surface 112 of the support assembly 11. For example, the recess 14 includes at least one annular recess 141 and at least one radial recess 143, wherein the annular recess 141 and the radial recess 143 are connected to each other. In addition, an inlet pipeline 15 can be provided inside the support assembly 11 to connect to the recess 14, and is used to transport a gas to the recess 14 located on the top surface 112 of the support assembly 11.

The diffusion unit 23 of the embodiment of the invention is made of a porous material, such as ceramic, silicon carbide (SiC), or foamed metal, and is connected to the top surface 112 of the support assembly 11, wherein the diffusion unit 23 includes a first diffusion region 231 and a second diffusion region 233.

The first diffusion region 231 and the second diffusion region 233 of the diffusion unit 23 have different permeability, wherein the second diffusion region 233 is located on the outer side of the first diffusion region 231, and the permeability of the first diffusion region 231 may be greater than that of the second diffusion region 233. For example, the first diffusion region 231 is disk-shaped, while the second diffusion region 233 is annular, wherein the second diffusion region 233 is annularly disposed around the first diffusion region 231.

It should be noted that the above-mentioned higher permeability of the first diffusion region 231 located on the inner side compared to the second diffusion region 233 is merely one embodiment of the invention and is not intended to limit the scope of the invention. In another embodiment of the invention, the permeability of the first diffusion region 231 and the second diffusion region 233 can be selected according to actual needs, such that the permeability of the first diffusion region 231 located on the inner side is smaller than that of the second diffusion region 233.

In one embodiment of the invention, the first diffusion region 231 and the second diffusion region 233 may be made of the same material. For example, when both the first diffusion region 231 and the second diffusion region 233 are made of foamed metal, the first diffusion region 231 and the second diffusion region 233 can be produced with different permeability by using different foaming temperatures and/or different foaming times. In other embodiments, the first diffusion region 231 and the second diffusion region 233 may be made of different materials with different permeability.

In one embodiment of the invention, the surfaces of the first diffusion region 231 and the second diffusion region 233 can be provided with a plurality of protrusions 133 as shown in FIG. 2, and at least one diffusion channel 135 is formed between adjacent protrusions 133.

The foregoing descriptions are merely preferred embodiments of this disclosure, and are not intended to limit the scope of this disclosure, that is, all equivalent changes and modifications made according to shapes, structures, features and spirits described in the scope of the claims of this disclosure shall fall within the scope of the claims of this disclosure.

What is claimed is:

1. A wafer holder for providing even temperature distribution, comprising:
a support assembly, comprising:
at least one recess disposed on a top surface of the support assembly;
an inlet pipeline connected to the recess for supplying a gas to the recess located on the top surface of the support assembly; and
a diffusion unit located on the top surface of the support assembly, wherein the diffusion unit is a porous material, comprising:
a main body including a bearing surface;
a plurality of protrusions located on the bearing surface of the main body for supporting at least one wafer;
at least one diffusion channel located between the plurality of protrusions.

2. The wafer holder for providing even temperature distribution according to claim 1, wherein the support assembly further comprises a base and a carrier unit, the carrier unit is disposed on the base, and the recess is formed on the carrier unit.

3. The wafer holder for providing even temperature distribution according to claim 2, wherein the carrier unit is a titanium disk and a thermal conductivity of the diffusion unit is greater than that of the titanium disk.

4. The wafer holder for providing even temperature distribution according to claim 1, wherein an area of the plurality of protrusions is between 30% and 70% of that of the bearing surface of the main body.

5. The wafer holder for providing even temperature distribution according to claim 1, wherein a height of the plurality of the protrusions is between 0.3 mm and 1 mm.

6. The wafer holder for providing even temperature distribution according to claim 5, wherein a diameter of the plurality of protrusions is between 6 mm and 10 mm, and a gap between adjacent protrusions is between 1 mm and 5 mm.

7. A wafer holder for providing even temperature distribution, comprising:
a support assembly, comprising:
at least one recess disposed on a top surface of the support assembly;
an inlet pipeline connected to the recess for supplying a gas to the recess located on the top surface of the support assembly; and
a diffusion unit located on the top surface of the support assembly, wherein the diffusion unit is a porous material, comprising:
a first diffusion region;
a second diffusion region located on the outer side of the first diffusion region, wherein the first diffusion region and the second diffusion region are used to support at least one wafer, and a gas permeability of the first diffusion region is different from that of the second diffusion region.

8. The wafer holder for providing even temperature distribution according to claim 7, wherein the gas permeability of the first diffusion region is greater than that of the second diffusion region.

9. The wafer holder for providing even temperature distribution according to claim 7, wherein the first diffusion region is disk-shaped, the second diffusion region is annular, and the second diffusion region is annularly disposed around the first diffusion region.

10. The wafer holder for providing even temperature distribution according to claim 7, comprising a plurality of protrusions disposed on the first diffusion region and the second diffusion region, and at least one diffusion channel formed between the plurality of protrusions.

11. The wafer holder for providing even temperature distribution according to claim 7, wherein the first diffusion region and the second diffusion region are foamed metal, and a foaming time and a foaming temperature for making the first diffusion region and the second diffusion region are different.
